(19) United States
(12) Patent Application Publication
(10) Pub. No.: US 2025/0081790 A1
(43) Pub. Date: Mar. 6, 2025

(54) DISPLAY DEVICE

(71) Applicant: SAMSUNG DISPLAY CO., LTD., Yongin-si (KR)

(72) Inventors: GAK SEOK LEE, Yongin-si (KR); MIN-HEE KIM, Yongin-si (KR); JAE CHEOL PARK, Yongin-si (KR); DANBI YANG, Yongin-si (KR); KEUNCHAN OH, Yongin-si (KR); SIMBUM YUK, Yongin-si (KR)

(21) Appl. No.: 18/754,990

(22) Filed: Jun. 26, 2024

(30) Foreign Application Priority Data
Aug. 28, 2023 (KR) 10-2023-0113138

(51) Int. Cl. H10K 59/38; H10K 59/122; H10K 59/80

(52) U.S. Cl. CPC H10K 59/38; H10K 59/122; H10K 59/873

(57) ABSTRACT

A display device includes a display panel including a circuit element layer and a light emitting element layer on the circuit element layer, and a first light conversion layer, a second light conversion layer, and a light transmitting layer on the display panel and spaced apart from one another. The light emitting element layer includes a pixel defining layer that defines light emitting openings that overlap the first light conversion layer, the second light conversion layer, and the light transmitting layer, a plurality of light emitting elements arranged in the light emitting openings, respectively, and a barrier wall on the pixel defining layer, the barrier wall being black in color. When viewed from above, the barrier wall is located between light emitting elements adjacent to each other among the plurality of light emitting elements and extends parallel to sides of the adjacent light emitting elements that face each other.

### CROSS-REFERENCE TO RELATED APPLICATION

The present application claims priority to and the benefit of Korean Patent Application No. 10-2023-0113138, filed on Aug. 28, 2023 in the Korean Intellectual Property Office, the entire disclosure of which is incorporated herein by reference.

### BACKGROUND

### 1. Field

Aspects of embodiments of the present disclosure relate to a display device.

### 2. Description of the Related Art

Multimedia display devices, such as televisions, mobile phones, tablets, computers, car navigation units, game machines, and the like, may include a display panel for displaying an image. The display panel may include a plurality of pixels for displaying an image, and each of the pixels may include a light emitting element that generates light and a drive element connected to the light emitting element.

A display device including light conversion layers and a light transmitting layer to improve color purity is being developed. The light conversion layers and the light transmitting layer are disposed on pixels. The light conversion layers convert light generated by the pixels into light having a different wavelength. The light transmitting layer transmits the light generated by the pixels. Each of the light conversion layers and the light transmitting layer is disposed to overlap a corresponding pixel among the pixels. Each of the light conversion layers includes quantum dots and a resin for converting the wavelength of light. The light transmitting layer includes scatterers and a resin.

### SUMMARY

According to an aspect of embodiments of the present disclosure, a display device with improved color purity is provided.

According to one or more embodiments, a display device includes a display panel including a circuit element layer and a light emitting element layer on the circuit element layer, and a first light conversion layer, a second light conversion layer, and a light transmitting layer on the display panel and spaced apart from one another. The light emitting element layer includes a pixel defining layer that defines light emitting openings that overlap the first light conversion layer, the second light conversion layer, and the light transmitting layer, a plurality of light emitting elements arranged in the light emitting openings, respectively, and a barrier wall located on the pixel defining layer, the barrier wall being black in color. When viewed from above a plane, the barrier wall is located between light emitting elements adjacent to each other among the plurality of light emitting elements and extends parallel to sides of the adjacent light emitting elements that face each other.

According to one or more embodiments, a display device includes a display panel and a first light conversion layer, a second light conversion layer, and a light transmitting layer disposed on the display panel and spaced apart from one another. The display panel includes a pixel defining layer that defines a plurality of pixel openings, a first light emitting element that is arranged in the pixel openings and that overlaps the first light conversion layer, a second light emitting element that is arranged in the pixel openings and that overlaps the second light conversion layer, a third light emitting element that is arranged in the pixel openings and spaced apart from the first light emitting element in a first direction and that overlaps the light transmitting layer, and a barrier wall located between the first light emitting element and the third light emitting element. When viewed from above a plane, a length of the barrier wall in a second direction crossing the first direction is longer than a length of the first light emitting element in the second direction and a length of the third light emitting element in the second direction.

### BRIEF DESCRIPTION OF THE DRAWINGS

The above and other aspects, objects, and features of the present disclosure will become more apparent by describing in further detail some embodiments thereof with reference to the accompanying drawings.

FIG. 1 is a perspective view of a display device according to an embodiment of the present disclosure.

FIG. 2 is a cross-sectional view of the display device according to an embodiment of the present disclosure.

FIG. 3 is a plan view of a display panel according to an embodiment of the present disclosure.

FIG. 4 is an equivalent circuit diagram of a pixel according to an embodiment of the present disclosure.

FIG. 5A is an enlarged plan view of a display region according to an embodiment of the present disclosure.

FIG. 5B is an enlarged plan view of a display region according to another embodiment of the present disclosure.

FIG. 6 is a cross-sectional view taken along the line I-I′ of FIG. 5A.

FIG. 7A is a cross-sectional view of a display device according to a comparative example.

FIG. 7B is a cross-sectional view of the display device according to an embodiment of the present disclosure.

FIGS. 8A to 8C are views for explaining color purity.

FIG. 9 is a cross-sectional view of a display device according to an embodiment of the present disclosure.

FIG. 10 is a cross-sectional view of a display device according to an embodiment of the present disclosure.

### DETAILED DESCRIPTION

The above and other aspects, features, and advantages of the present disclosure will become apparent from the following description of embodiments given in conjunction with the accompanying drawings. However, the present disclosure is not limited to the embodiments disclosed herein and may be implemented in various different forms. Herein, some embodiments are provided to provide complete disclosure of the present disclosure and to provide thorough understanding of the present disclosure to those skilled in the art to which the present disclosure pertains, and the scope of the present disclosure is set forth by the accompanying claims and equivalents thereof. Like reference numerals refer to like elements throughout.

When an element or layer is referred to as being “on” another element or layer, it may be directly on the other element or layer, or one or more intervening elements or layers may be present. In contrast, when an element is referred to as being “directly on” another element or layer, there are no intervening elements or layers present. As used herein, the term “and/or” includes each of mentioned items and all combinations of one or more of the items.

Spatially relative terms, such as “below,” “beneath,” “lower,” “above,” “upper,” and the like, may be used to easily describe a correlation between one element or component and another element or component as illustrated in the drawings. The spatially relative terms are to be understood as terms including different directions of an element during use or operation in addition to the direction illustrated in the drawings. Like reference numerals refer to like elements throughout.

Although the terms “first,” “second,” and the like are used herein to describe various elements, components, and/or sections, these elements, components, and/or sections are not to be limited by these terms. These terms are used to distinguish one element, component, or section from another element, component, or section. Accordingly, a first element, a first component, or a first section mentioned below could be termed a second element, a second component, or a second section within the spirit and scope of the present disclosure.

Embodiments described herein will be described with reference to plan views and cross-sectional views which may be idealized schematic views of the present disclosure. Accordingly, the forms of illustrative drawings may be changed according to manufacturing technology and/or allowable errors. Embodiments of the present disclosure are not limited to specific forms illustrated, but include changes in the forms generated according to manufacturing processes. Regions illustrated in the drawings have schematic properties, and the shapes of the regions illustrated in the drawings may illustrate specific forms of regions of devices and are not intended to limit the scope of the present disclosure.

Herein, some embodiments of the present disclosure will be described in further detail with reference to the accompanying drawings.

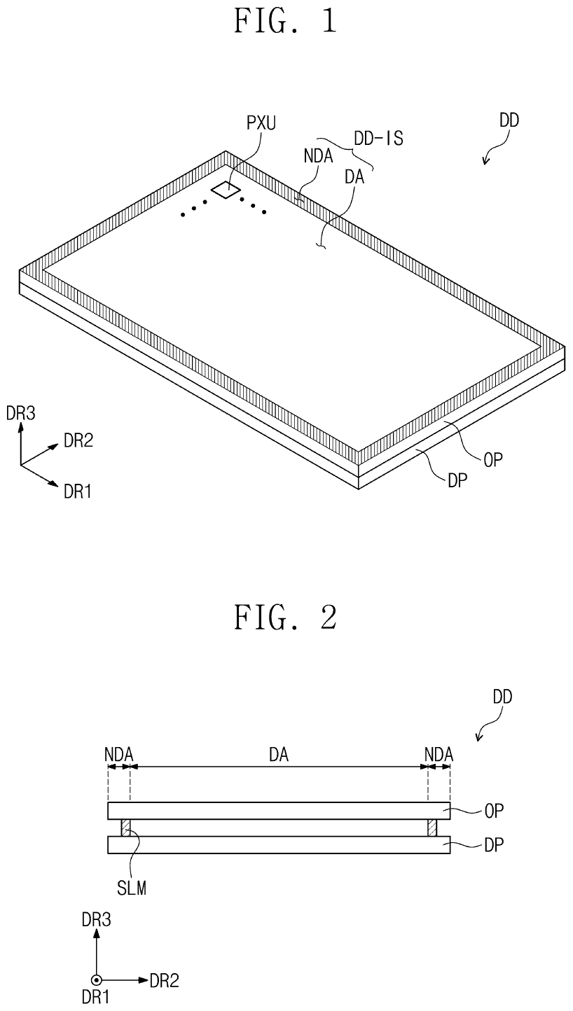

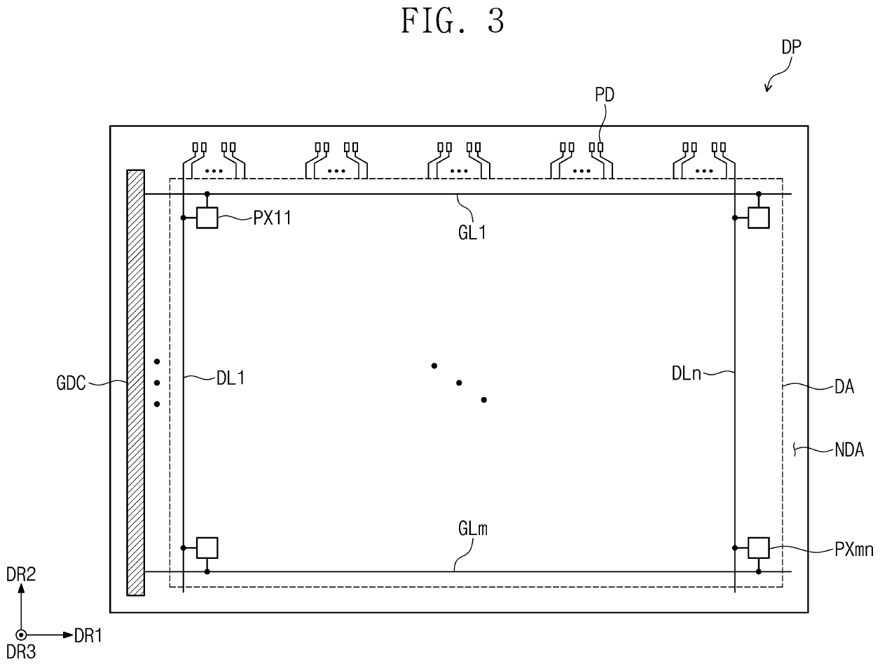

FIG. 1 is a perspective view of a display device according to an embodiment of the present disclosure; and FIG. 2 is a cross-sectional view of the display device according to an embodiment of the present disclosure.

Referring to FIG. 1, in an embodiment, a display device DD may have a rectangular shape with long sides extending in a first direction DR1 and short sides extending in a second direction DR2 crossing the first direction DR1. However, without being limited thereto, the display device DD may have any of various shapes such as a circular shape, a polygonal shape, and the like.

Herein, a direction substantially perpendicular to a plane defined by the first direction DR1 and the second direction DR2 is defined as a third direction DR3. Further, the expression “when viewed from above the plane” used herein may mean that it is viewed in the third direction DR3.

The display device DD may display an image through a display surface DD-IS. The display surface DD-IS may be parallel to the plane defined by the first direction DR1 and the second direction DR2. The upper surface of an uppermost member of the display device DD with respect to the third direction DR3 may be defined as the display surface DD-IS. Further, front surfaces (or upper surfaces) and rear surfaces (or lower surfaces) of layers or units to be described below may be distinguished from each other based on the third direction DR3.

The display device DD may include a display region DA and a non-display region NDA. Unit pixels PXU may be disposed in the display region DA and may not be disposed in the non-display region NDA. The non-display region NDA may be defined along a periphery of the display surface DD-IS. In an embodiment, the non-display region NDA may surround the display region DA. However, in an embodiment of the present disclosure, the non-display region NDA may be omitted, or may be disposed on only one side of the display region DA. FIG. 1 illustrates the display device DD of a flat type. However, the display device DD may have a curved shape, or may be foldable, rollable, or slidable from a housing.

The unit pixels PXU illustrated in FIG. 1 may define pixel rows and pixel columns. Each of the unit pixels PXU may be a minimum repeat unit. The unit pixel PXU may include at least one pixel. The unit pixel PXU may include a plurality of pixels that provide light of different colors.

Referring to FIG. 2, the display device DD may include a display panel DP and a light control layer OP that faces the display panel DP and that is spaced apart from the display panel DP. The display panel DP may be referred to as a lower display substrate, and the light control layer OP may be referred to as an upper display substrate. A cell gap may be formed between the display panel DP and the light control layer OP. The cell gap may be maintained by a sealing member SLM that couples the display panel DP and the light control layer OP. The sealing member SLM may include a binder resin and inorganic fillers mixed in the binder resin. The sealing member SLM may further include other additives. The additives may include an amine-based curing agent and a photo-initiator. The additives may further include a silane additive and an acrylic additive. In an embodiment, the sealing member SLM may include an inorganic material such as a frit.

In each of the display panel DP and the light control layer OP, a display region DA and a non-display region NDA may be defined to correspond to the display region DA and the non-display region NDA of the display device DD. Herein, the display region DA of the display device DD may refer to the display region DA of each of the display panel DP and the light control layer OP, and the non-display region NDA of the display device DD may refer to the non-display region NDA of each of the display panel DP and the light control layer OP.

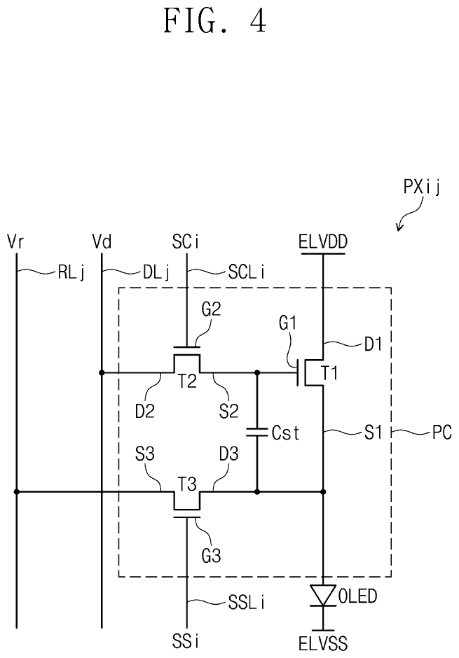

FIG. 3 is a plan view of the display panel according to an embodiment of the present disclosure.

Referring to FIG. 3, an arrangement relationship between signal lines GL1 to GLm and DL1 to DLn and pixels PX11 to PXmn on the plane is illustrated. The signal lines GL1 to GLm and DL1 to DLn may include a plurality of gate lines GL1 to GLm and a plurality of data lines DL1 to DLn.

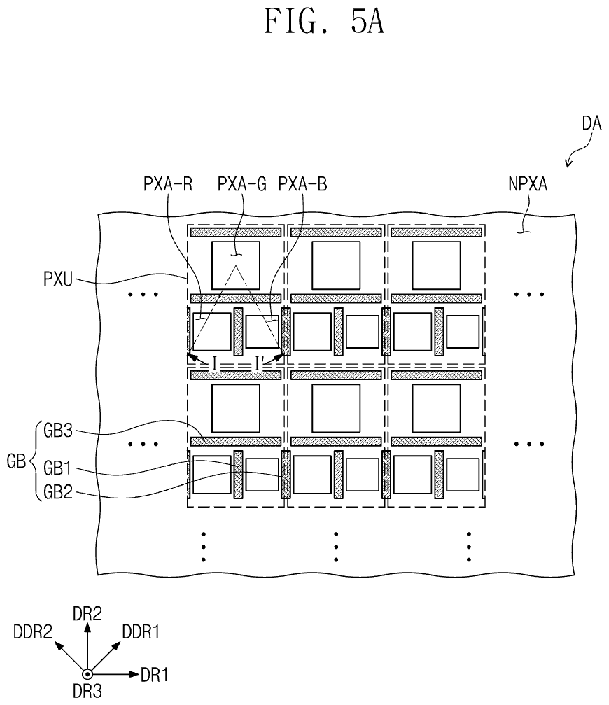

Each of the pixels PX11 to PXmn may be connected to a corresponding gate line among the plurality of gate lines GL1 to GLm and a corresponding data line among the plurality of data lines DL1 to DLn. Each of the pixels PX11 to PXmn may include a pixel drive circuit and a light emitting element. The display panel DP may include more types of signal lines depending on the configurations of the pixel drive circuits of the pixels PX11 to PXmn. For example, each of the gate lines GL1 to GLm may include a corresponding scan line SCLi (refer to FIG. 4) and a corresponding sensing line SSLi (refer to FIG. 4).

A gate drive circuit GDC may be integrated into the display panel DP through an oxide semiconductor gate driver circuit (OSG) process or an amorphous silicon gate driver circuit (ASG) process. The gate drive circuit GDC connected to the gate lines GL1 to GLm may be disposed on a side of the non-display region NDA in the first direction DR1. Pads PD connected to ends of the plurality of data lines DL1 to DLn may be disposed on a side of the non-display region NDA in the second direction DR2.

FIG. 4 is an equivalent circuit diagram of a pixel according to an embodiment of the present disclosure.

Referring to FIG. 4, a pixel PXij connected to an i-th scan line SCLi, an i-th sensing line SSLi, a j-th data line DLj, and a j-th reference line RLj is illustrated as an example. The pixel PXij may include a pixel circuit PC and a light emitting element OLED connected to the pixel circuit PC. The pixel circuit PC may include a plurality of transistors T1, T2, and T3 and a capacitor Cst. The plurality of transistors T1, T2, and T3 may be formed through a low-temperature polycrystalline silicon (LTPS) process or a low-temperature polycrystalline oxide (LTPO) process. Although it is described that the plurality of transistors T1, T2, and T3 are N-type transistors, at least one of the transistors T1, T2, and T3 may be implemented with a P-type transistor.

In an embodiment, the pixel circuit PC that includes the first transistor T1, the second transistor T2, the third transistor T3, and the capacitor Cst is illustrated as an example. However, the pixel circuit PC is not limited thereto. The first transistor T1 may be a drive transistor, the second transistor T2 may be a switching transistor, and the third transistor T3 may be a sensing transistor. The pixel circuit PC may further include an additional transistor, or may further include an additional capacitor.

The light emitting element OLED may be an organic light emitting element or an inorganic light emitting element that includes an anode (a first electrode) and a cathode (a second electrode). The anode of the light emitting element OLED may receive a first voltage ELVDD through the first transistor T1, and the cathode of the light emitting element OLED may receive a second voltage ELVSS. The light emitting element OLED may emit light by receiving the first voltage ELVDD and the second voltage ELVSS.

The first transistor T1 may include a drain D1 that receives the first voltage ELVDD, a source S1 connected to the anode of the light emitting element OLED, and a gate G1 connected to the capacitor Cst. The first transistor T1 may control a drive current flowing to the light emitting element OLED from the first voltage ELVDD in response to a voltage value stored in the capacitor Cst.

The second transistor T2 may include a drain D2 connected to the j-th data line DLj, a source S2 connected to the capacitor Cst, and a gate G2 that receives the i-th first scan signal SCi. The j-th data line DLj may receive a data voltage Vd. The second transistor T2 may provide the data voltage Vd to the first transistor T1 in response to the i-th first scan signal SCi.

The third transistor T3 may include a source S3 connected to the j-th reference line RLj, a drain D3 connected to the anode of the light emitting element OLED, and a gate G3 that receives the i-th second scan signal SSi. The j-th reference line RLj may receive a reference voltage Vr. The third transistor T3 may initialize the capacitor Cst and the anode of the light emitting element OLED.

The capacitor Cst may store a voltage corresponding to a difference between a voltage received from the second transistor T2 and the first voltage ELVDD. The capacitor Cst may be connected to the gate G1 of the first transistor T1 and the anode of the light emitting element OLED.

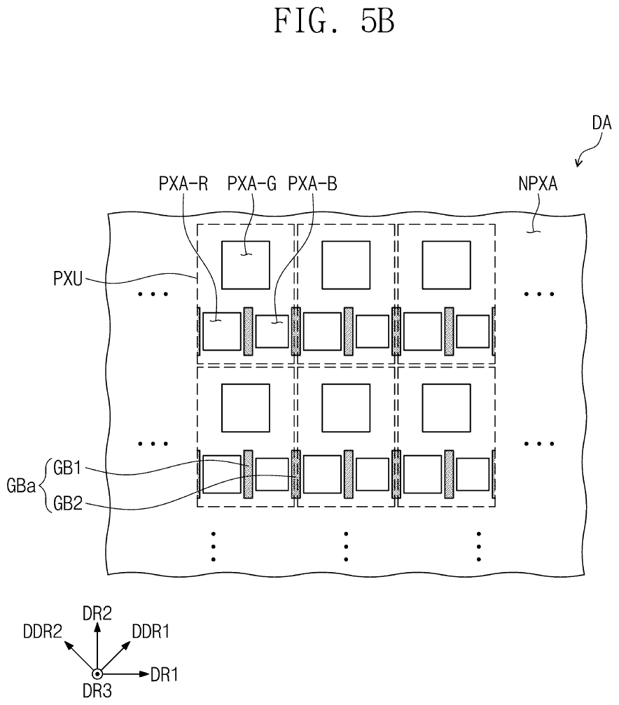

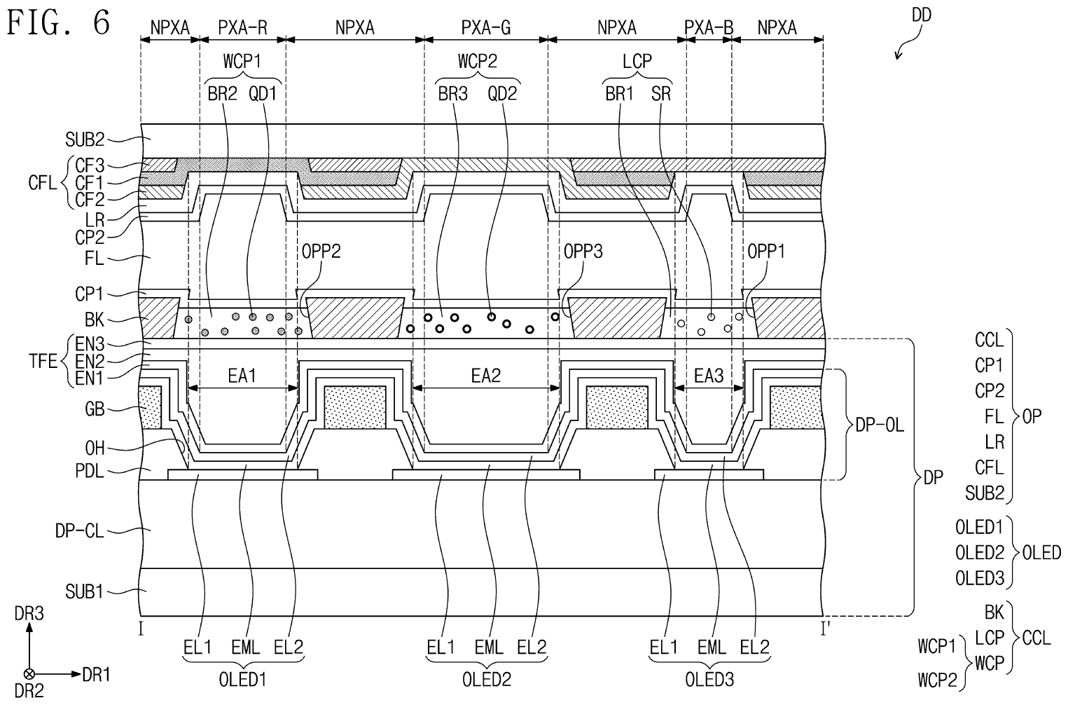

FIG. 5A is an enlarged plan view of the display region according to an embodiment of the present disclosure. FIG. 5B is an enlarged plan view of the display region according to another embodiment of the present disclosure.

Description of FIG. 5B will be focused on a difference from FIG. 5A.

Referring to FIGS. 5A and 5B, the display region DA may include the plurality of unit pixels PXU and a peripheral region NPXA. The unit pixels PXU may be arranged in the first direction DR1 and the second direction DR2. Although six unit pixels PXU are illustrated as an example in FIG. 5A, a number of unit pixels PXU is not limited thereto. Herein, one unit pixel PXU among the plurality of unit pixels PXU will be described.

The unit pixel PXU may include a first pixel, a second pixel, and a third pixel that emit light of different colors. The first pixel, the second pixel, and the third pixel may output red light, green light, and blue light, respectively. In FIG. 5A, a first pixel region PXA-R, a second pixel region PXA-G, and a third pixel region PXA-B are illustrated with respect to the first pixel, the second pixel, and the third pixel, respectively. The first pixel region PXA-R may be a region through which light generated by the first pixel is provided to the outside, the second pixel region PXA-G may be a region through which light generated by the second pixel is provided to the outside, and the third pixel region PXA-B may be a region through which light generated by the third pixel is provided to the outside.

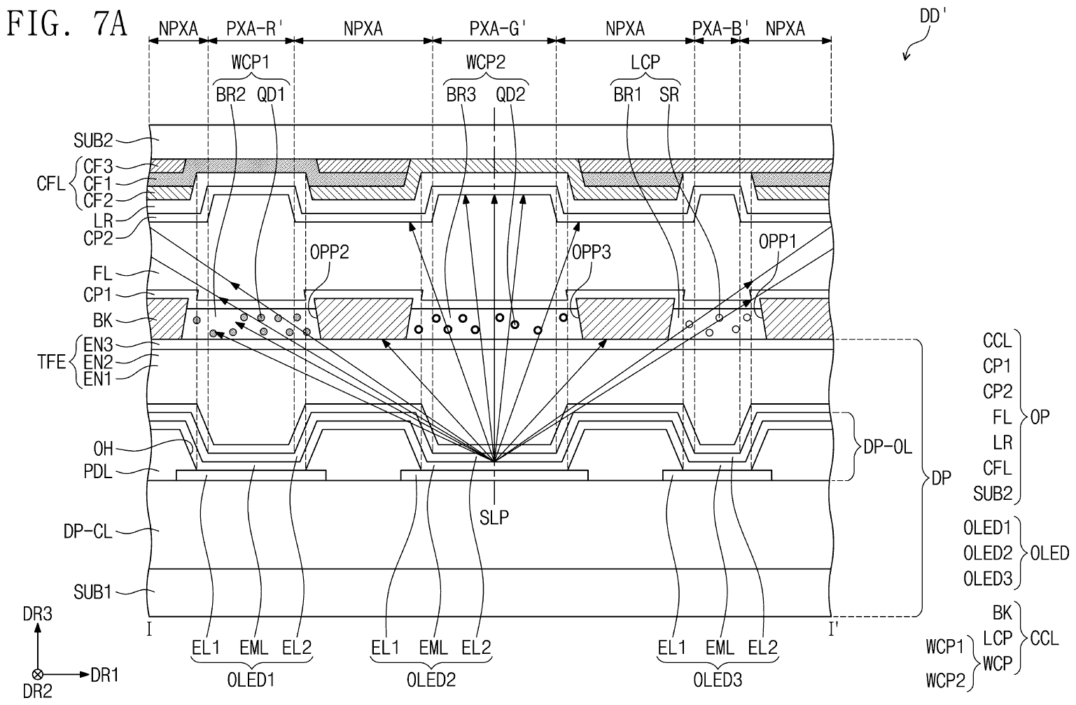

Although not illustrated, the first pixel may include a first light emitting element OLED1 (refer to FIG. 6) and a first light conversion layer WCP1 (refer to FIG. 6). The second pixel may include a second light emitting element OLED2 (refer to FIG. 6) and a second light conversion layer WCP2 (refer to FIG. 6). The third pixel may include a third light emitting element OLED3 (refer to FIG. 6) and a light transmitting layer LCP (refer to FIG. 6). The first to third pixel regions PXA-R, PXA-G, and PXA-B may correspond to regions through which light provided from the light emitting elements OLED, which will be described below with reference to FIG. 6, is emitted. A further detailed description thereof will be provided below with reference to FIG. 6.

When viewed from above the plane, the first pixel region PXA-R and the second pixel region PXA-G may be arranged in a first diagonal direction DDR1. The first pixel region PXA-R and the third pixel region PXA-B may be arranged in the first direction DR1. The second pixel region PXA-G and the third pixel region PXA-B may be arranged in a second diagonal direction DDR2. The first diagonal direction DDR1 may be defined as a direction crossing the first direction DR1 and the second direction DR2. The second diagonal direction DDR2 may be defined as a direction crossing the first diagonal direction DDR1. However, an arrangement of the first to third pixel regions PXA-R, PXA-G, and PXA-B is not limited thereto, and the first to third pixel regions PXA-R, PXA-G, and PXA-B may be arranged in various forms.

In an embodiment, the first to third pixel regions PXA-R, PXA-G, and PXA-B may have a rectangular shape when viewed from above the plane. However, without being limited thereto, the first to third pixel regions PXA-R, PXA-G, and PXA-B may have different shapes.

For example, when viewed from above the plane, an area of the second pixel region PXA-G may be greater than areas of the first and third pixel regions PXA-R and PXA-B. When viewed from above the plane, the area of the first pixel region PXA-R may be greater than the area of the third pixel region PXA-B. That is, the second pixel region PXA-G may have the largest area, and the third pixel region PXA-B may have the smallest area.

However, the embodiments illustrated in FIGS. 5A and 5B are illustrative, and depending on a design of the display module DM, the shapes, areas, and arrangement of the first to third pixel regions PXA-R, PXA-G, and PXA-B may vary depending on light emission efficiency.

The peripheral region NPXA may be disposed to surround the first pixel region PXA-R, the second pixel region PXA-G, and the third pixel region PXA-B. In addition, the peripheral region NPXA may be disposed between the first pixel region PXA-R, the second pixel region PXA-G, and the third pixel region PXA-B. The peripheral region NPXA may set boundaries between the first pixel region PXA-R, the second pixel region PXA-G, and the third pixel region PXA-B.

Referring to FIG. 5A, the unit pixel PXU may further include barrier walls GB. The barrier walls GB may be disposed between the first pixel region PXA-R, the second pixel region PXA-G, and the third pixel region PXA-B.

In an embodiment, the barrier walls GB may include a first barrier wall GB1, a second barrier wall GB2, and a third barrier wall GB3. When viewed from above the plane, the first barrier wall GB1 may be disposed between the first pixel region PXA-R and the third pixel region PXA-B that are disposed in the same unit pixel PXU.

The first barrier wall GB1 may extend in the second direction DR2. The first barrier wall GB1 may extend parallel to sides of the first pixel region PXA-R and the third pixel region PXA-B. In an embodiment, a length of the first barrier wall GB1 in the second direction DR2 may be longer than a length of the first pixel region PXA-R in the second direction DR2 and a length of the third pixel region PXA-B in the second direction DR2.

The second barrier wall GB2 may be disposed between the first pixel region PXA-R and the third pixel region PXA-B that are disposed in different unit pixels PXU. The second barrier wall GB2 may be disposed to overlap a boundary between the unit pixels PXU adjacent to each other in the first direction DR1. The second barrier wall GB2 may be disposed between the first pixel region PXA-R disposed in a first unit pixel PXU among the plurality of unit pixels PXU and the third pixel region PXA-B disposed in a second unit pixel PXU adjacent to the first unit pixel PXU in the first direction DR1.

The second barrier wall GB2 may extend in the second direction DR2. The second barrier wall GB2 may extend parallel to sides of the first pixel region PXA-R and the third pixel region PXA-B. A length of the second barrier wall GB2 in the second direction DR2 may be longer than a length of the first pixel region PXA-R in the second direction DR2 and a length of the third pixel region PXA-B in the second direction DR2.

The third barrier wall GB3 may be disposed between the first pixel region PXA-R and the second pixel region PXA-G. The third barrier wall GB3 may be disposed between the third pixel region PXA-B and the second pixel region PXA-G. The third barrier wall GB3 may extend in the first direction DR1. The third barrier wall GB3 may extend parallel to a side of the second pixel region PXA-G.

A length of the third barrier wall GB3 in the first direction DR1 may be longer than a length of the second pixel region PXA-G in the first direction DR1. The length of the third barrier wall GB3 in the first direction DR1 may be longer than a length from a first side of the first pixel region PXA-R to a first side of the third pixel region PXA-B. The first side of the first pixel region PXA-R may be defined as a side facing away from an opposite side of the first pixel region PXA-R that faces the third pixel region PXA-B in the first direction DR1. The first side of the third pixel region PXA-B may be defined as a side facing away from an opposite side of the third pixel region PXA-B that faces the first pixel region PXA-R in the first direction DR1.

Referring to FIG. 5B, a barrier wall GBa may include a first barrier wall GB1 and a second barrier wall GB2. However, the third barrier wall GB3 (refer to FIG. 5A) may be omitted.

The first barrier wall GB1 may be disposed between the first pixel region PXA-R and the third pixel region PXA-B disposed adjacent to each other in the first direction DR1 in one unit pixel PXU.

The second barrier wall GB2 may be disposed between the first pixel region PXA-R and the third pixel region PXA-B that are disposed in different unit pixels PXU. The second barrier wall GB2 may be disposed to overlap the boundary between the unit pixels PXU adjacent to each other in the first direction DR1.

FIG. 6 is a cross-sectional view taken along the line I-I′ of FIG. 5A.

For convenience of description, the first barrier wall GB1, the second barrier wall GB2, and the third barrier wall GB3 of FIG. 5A will be defined as the barrier walls GB.

Referring to FIG. 6, the display device DD may include the display panel DP and the light control layer OP. The light control layer OP may be disposed on the display panel DP.

The display layer DP may include a lower substrate SUB1, a circuit layer DP-CL, a light emitting element layer DP-OL, and an encapsulation layer TFE. In a step of manufacturing the display panel DP, an insulating layer, a semiconductor layer, and a conductive layer may be formed on the lower substrate SUB1 by a process such as coating, deposition, or the like. Thereafter, the insulating layer, the semiconductor layer, and the conductive layer may be selectively subjected to patterning by a photolithography process. A semiconductor pattern, a conductive pattern, a signal line, and the like included in the display panel DP may be formed through the above-described process.

The lower substrate SUB1 may provide a base surface on which the circuit layer DP-CL is to be formed. The lower substrate SUB1 may have a single-layer structure or a multi-layer structure. For example, the lower substrate SUB1 having a multi-layer structure may include synthetic resin layers and at least one inorganic layer disposed between the synthetic resin layers, or may include a glass substrate and a synthetic resin layer disposed on the glass substrate. However, embodiments of the lower substrate SUB1 are not limited thereto.

The synthetic resin layer(s) included in the lower substrate SUB1 may include at least one of an acrylic resin, a methacrylic resin, a polyisoprene resin, a vinyl resin, an epoxy resin, a urethane-based resin, a celluosic resin, a siloxane-based resin, a polyamide resin, a perylene-based resin, and a polyimide resin. However, the material of the synthetic resin layer(s) is not limited to the above examples.

Although not illustrated, the circuit layer DP-CL may include drive elements constituting equivalent circuits of the pixels. For example, the circuit layer DP-CL may include at least one insulating layer, transistors connected to the light emitting elements OLED1, OLED2, and OLED3 that will be described below, at least one capacitor, and signal lines. A plurality of transistors may be provided. The plurality of transistors and the capacitor may be connected together. The transistor may include a semiconductor pattern, and the semiconductor pattern may be arranged, such as according to a predetermined rule, on the plane depending on the configuration of the equivalent circuits of the pixels. The semiconductor pattern may include poly silicon, amorphous silicon, crystalline oxide, or non-crystalline oxide.

The light emitting element layer DP-OL may be disposed on the circuit layer DP-CL. The light emitting element layer DP-OL may include a plurality of first electrodes EL1, an emissive layer EML, a second electrode EL2, and a pixel defining layer PDL.

The first electrodes EL1 may be disposed on the circuit layer DP-CL. The first electrodes EL1 may be anodes or cathodes. Further, the first electrodes EL1 may be pixel electrodes. The first electrodes EL1 may be transmissive electrodes, transflective electrodes, or reflective electrodes.

The pixel defining layer PDL may be disposed on the circuit layer DP-CL. The pixel defining layer PDL may cover portions of the first electrodes EL1. Light emitting openings OH may be defined by the pixel defining layer PDL. The light emitting openings OH of the pixel defining layer PDL may expose at least portions of the first electrodes EL1.

First to third emissive regions EA1, EA2, and EA3 may be defined to correspond to the portions of the first electrodes EL1 exposed by the light emitting openings OH of the pixel defining layer PDL. The first emissive region EA1 may correspond to the first pixel region PXA-R. The second emissive region EA2 may correspond to the second pixel region PXA-G. The third emissive region EA3 may correspond to the third pixel region PXA-B. A region other than the first to third emissive regions EA1, EA2, and EA3 may be defined as a non-emissive region.

The expression “corresponding to” used herein means that two components overlap each other when viewed in the thickness direction DR3 of the display device DD and is not limited to the same area. The first to third emissive regions EA1, EA2, and EA3 may overlap the first to third pixel regions PXA-R, PXA-G, and PXA-B, respectively.

The barrier walls GB may be disposed on an upper surface of the pixel defining layer PDL. In an embodiment, the barrier walls GB may include a black coloring agent. For example, the black coloring agent may include carbon black, a metal, such as chromium, or an oxide thereof. However, embodiments of the barrier walls GB are not limited thereto.

In an embodiment, the barrier walls GB may have a thickness of 1 μm to 3 μm.

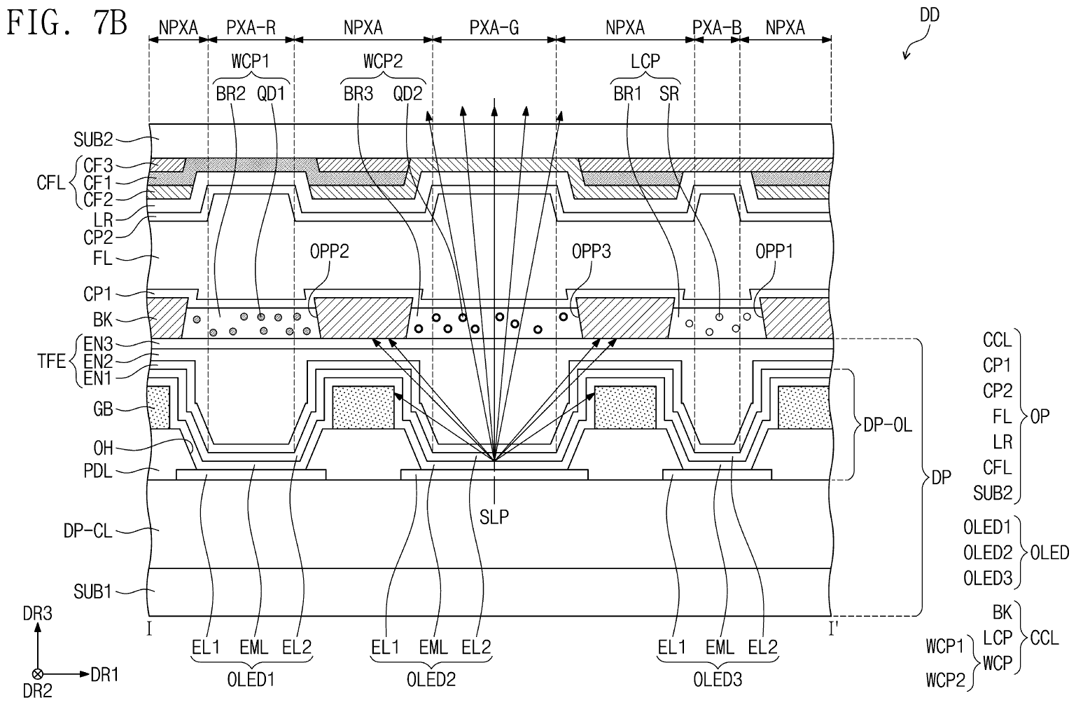

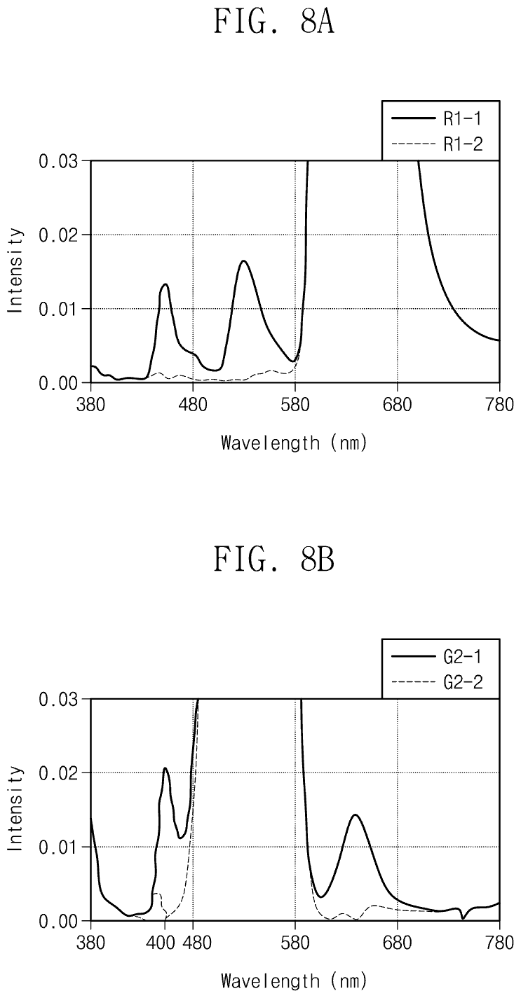

In an embodiment, the barrier walls GB include the black coloring agent, and the barrier walls GB may thereby absorb a portion of light output from the light emitting elements OLED. A further detailed description thereof will provided below with reference to FIG. 7A.

The emissive layer EML may be disposed on the first electrodes EL1. The emissive layer EML may be disposed on the pixel defining layer PDL and the barrier walls GB. The emissive layer EML may be commonly disposed in the first to third emissive regions EA1, EA2, and EA3 and the non-emissive region. The emissive layer EML may be disposed in the light emitting openings OH. The emissive layer EML may cover the pixel defining layer PDL and the barrier walls GB.

The emissive layer EML may generate source light. In an embodiment, the emissive layer EML may emit blue light. In the display device DD according to an embodiment, blue light may be defined as the source light. When the emissive layer EML is divided to correspond to the first to third emissive regions EA1, EA2, and EA3, the emissive layers EML may all emit blue light, or the first to third emissive regions EA1, EA2, and EA3 may emit light in different wavelength ranges.

The emissive layer EML may have a single-layer structure formed of a single material, a single-layer structure formed of a plurality of different materials, or a multi-layer structure having a plurality of layers formed of a plurality of different materials. The emissive layer EML may include a fluorescent material or a phosphorescent material. In the light emitting elements according to an embodiment, the emissive layer EML may include an organic luminescent material, a metal organic complex, or quantum dots as a luminescent material.

The second electrode EL2 may be disposed on the emissive layer EML. The second electrode EL2 may cover the emissive layer EML. The second electrode EL2 may be a common electrode. The second electrode EL2 may be a cathode or an anode, but embodiments of the second electrode EL2 are not limited thereto. For example, when the first electrodes EL1 are anodes, the second electrode EL2 may be a cathode, and when the first electrodes EL1 are cathodes, the second electrode EL2 may be an anode. The second electrode EL2 may be a transmissive electrode, a transflective electrode, or a reflective electrode.

Referring to FIGS. 5A and 6, the first electrodes EL1, the portions of the emissive layer EML, and the portions of the second electrode EL2 that are disposed in the light emitting openings OH may be defined as the light emitting elements OLED. The light emitting elements OLED may be disposed in the light emitting openings OH.

When viewed from above the plane, the barrier walls GB may be disposed between the adjacent pixel regions PXA-R, PXA-G, and PXA-B. The light emitting elements OLED may overlap the first pixel region PXA-R, the second pixel region PXA-G, and the third pixel region PXA-B. Among the light emitting elements OLED, the light emitting element OLED overlapping the first pixel region PXA-R may be defined as the first light emitting element OLED1. Among the light emitting elements OLED, the light emitting element OLED overlapping the second pixel region PXA-G may be defined as the second light emitting element OLED2. Among the light emitting elements OLED, the light emitting element OLED overlapping the third pixel region PXA-B may be defined as the third light emitting element OLED3.

When viewed from above the plane, the barrier walls GB may be disposed between sides of the adjacent light emitting elements OLED that face each other and may extend parallel to the sides of the light emitting elements OLED.

Although not illustrated, the light emitting elements OLED may further include light-emitting functional layers, such as hole control layers and electron control layers, which are disposed between the first electrodes EL1 and the second electrode EL2. The hole control layers may be disposed between the first electrodes EL1 and the emissive layer EML and may include at least one of a hole transport layer and a hole injection layer. The electron control layers may be disposed between the emissive layer EML and the second electrode EL2 and may include at least one of an electron transport layer and an electron injection layer. The light-emitting functional layers may be provided as common layers and may overlap the pixel regions PXA-R, PXA-G, and PXA-B and the peripheral region NPXA.

Referring to FIG. 6, the encapsulation layer TFE may be disposed on the light emitting element layer DP-OL. The encapsulation layer TFE may seal the light emitting element layer DP-OL. In an embodiment, the encapsulation layer TFE may include first to third encapsulation films EN1, EN2, and EN3. The first encapsulation film EN1 may be disposed on the second electrode EL2 and may cover the second electrode EL2. The second encapsulation film EN2 and the third encapsulation film EN3 may be sequentially disposed on the first encapsulation film EN1.

In an embodiment, the first and third encapsulation films EN1 and EN3 may include an inorganic film, and the inorganic film may protect the light emitting element layer DP-OL from moisture and/or oxygen. For example, the inorganic film may include at least one of aluminum oxide, titanium oxide, silicon oxide, silicon nitride, silicon oxy nitride, zirconium oxide, and hafnium oxide, but is not limited thereto.

In an embodiment, the second encapsulation film EN2 may include an organic film, and the organic film may protect the light emitting element layer DP-OL from foreign matter, such as dust particles. For example, the organic film may include an acrylic resin, but is not limited thereto.

The light control layer OP may be disposed on the display panel DP. In an embodiment, the light control layer OP may include a light adjustment layer CCL, a first capping layer CP1, a filling member FL, a second capping layer CP2, a low-refractive index layer LR, a color filter layer CFL, and an upper substrate SUB2.

The light adjustment layer CCL may be disposed on the encapsulation layer TFE. The light adjustment layer CCL may include a bank layer BK, the light transmitting layer LCP, and light conversion layers WCP.

The bank layer BK may be disposed on an upper surface of the third encapsulation film EN3. Although a plurality of bank layers BK are illustrated in FIG. 6, the bank layer BK may be substantially integrally formed. The bank layer BK may overlap the peripheral region NPXA. The bank layer BK may overlap the pixel defining layer PDL and the barrier walls GB.

In an embodiment, the bank layer BK may include a black pigment and water-repellent materials. In an embodiment, the bank layer BK includes the black pigment, and the bank layer BK may be black in color. Accordingly, to prevent or substantially prevent color mixing between light emitted from the light emitting elements OLED, the bank layer BK may block the light.

The bank layer BK may define a first control opening OPP1, a second control opening OPP2, and a third control opening OPP3.

The light transmitting layer LCP may be disposed on the third encapsulation film EN3. The light transmitting layer LCP may be disposed in the first control opening OPP1. The light transmitting layer LCP may be disposed in the third pixel region PXA-B. The light transmitting layer LCP may overlap the third emissive region EA3.

The light transmitting layer LCP may include a first base resin BR1 and scatterers SR dispersed in the first base resin BR1. The scatterers SR may scatter light incident from the third light emitting element OLED3 disposed in the third emissive region EA3 in various directions. The scatterers SR may be particles having a relatively high density or specific gravity. For example, the scatterers SR may include titanium oxide (TiOx) or silica-based nanoparticles. The scatterers SR may improve light emission efficiency of light that is provided from the third light emitting element OLED3 and that transmits through the light transmitting layer LCP.

The light transmitting layer LCP may provide source light (or blue light) provided from the third light emitting element OLED3, and the source light may pass through the light transmitting layer LCP and may be output toward the front surface of the display device DD.

The light conversion layers WCP may be disposed in the second control opening OPP2 and the third control opening OPP3. The light conversion layers WCP may be disposed on the display panel DP. The light conversion layers WCP and the light transmitting layer LCP may be disposed on the same layer.

The light conversion layers WCP may overlap the first pixel region PXA-R and the second pixel region PXA-G. The light conversion layers WCP may overlap the first light emitting element OLED1 and the second light emitting element OLED2.

The light conversion layers WCP may include the first light conversion layer WCP1 and the second light conversion layer WCP2. The first light conversion layer WCP1 may be disposed in the second control opening OPP2. The second light conversion layer WCP2 may be disposed in the third control opening OPP3. When viewed in the second direction DR2, the light transmitting layer LCP and the first and second light conversion layers WCP1 and WCP2 may be arranged in the direction opposite to the first direction DR1 in the order of the light transmitting layer LCP, the second light conversion layer WCP2, and the first light conversion layer WCP1.

The first light conversion layer WCP1 may be disposed in the first pixel region PXA-R. The first light conversion layer WCP1 may overlap the first light emitting element OLED1. The second light conversion layer WCP2 may be disposed in the second pixel region PXA-G. The second light conversion layer WCP2 may overlap the second light emitting element OLED2.

The width of the second light conversion layer WCP2 in the first direction DR1 may be greater than the widths of the first light conversion layer WCP1 and the light transmitting layer LCP in the first direction DR1. The width of the first light conversion layer WCP1 in the first direction DR1 may be greater than the width of the light transmitting layer LCP in the first direction DR1. That is, the second light conversion layer WCP2 may have the largest width in the first direction DR1, and the light transmitting layer LCP may have the smallest width in the first direction DR1.

The first light conversion layer WCP1 may include a second base resin BR2 and first quantum dots QD1 dispersed in the second base resin BR2. The second light conversion layer WCP2 may include a third base resin BR3 and second quantum dots QD2 dispersed in the third base resin BR3.

Cores of the quantum dots QD1 and QD2 included in the first light conversion layer WCP1 and the second light conversion layer WCP2 may be selected from any of a Group II-VI compound, a Group III-VI compound, a Group I-III-VI compound, a Group III-V compound, a Group IV-VI compound, a Group IV element, a Group IV compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and mixtures thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and a quarternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group III-VI compound may include a binary compound such as In₂S₃ or In₂Se₃, a ternary compound such as InGaS₃ or InGaSe₃, or any combination thereof.

The Group I-III-VI compound may be selected from a ternary compound selected from the group consisting of AgInS, AgInS₂, CuInS, CuInS₂, AgGaS₂, CuGaS₂, CuGaO₂, AgGaO₂, AgAlO₂, and mixtures thereof or a quarternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quarternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. The Group III-V compound may further include Group II metal. For example, InZnP may be selected as a Group III-II-V compound.

The Group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quarternary compound selected from the group consisting of SnPbSSe, SnPbSeTe, SnPbSTe, and mixtures thereof. The Group IV element may be selected from the group consisting of Si, Ge, and a mixture thereof. The Group IV compound may be a binary compound selected from the group consisting of SiC, SiGe, and a mixture thereof.

The elements included in the multi-element compounds, such as the binary compounds, the ternary compounds, and the quarternary compounds, may exist in particles at uniform or non-uniform concentrations. That is, the chemical formulas may refer to the types of elements included in the compounds, and the element ratios in the compounds may be different from one another. For example, AgInGaS₂ may mean AgInₓGa₁₋ₓS₂ (x being a real number between 0 and 1).

The quantum dots may have a single structure or a core-shell dual structure in which the concentrations of elements included in a corresponding quantum dot are uniform. For example, the material included in the core and the material included in the shell may be different from each other.

In an embodiment, the quantum dots QD1 and QD2 may have a core-shell structure including nanocrystals. The shell of each quantum dot may serve as a protective layer for maintaining semiconductor characteristics by preventing or substantially preventing chemical modification of the core and/or a charging layer for imparting electrophoretic characteristics to the quantum dot. The shell may have a single layer or multiple layers. The interface between the core and the shell may have a concentration gradient in which the concentration of an element existing in the shell is lowered toward the center. The shell of the quantum dot may be, for example, a metal oxide, a non-metal oxide, a semiconductor compound, or a combination thereof.

For example, the metal oxide and the non-metal oxide may include a binary compound such as SiO₂, AL₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the materials are not limited thereto.

The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb, but the material is not limited thereto.

The elements included in the multi-element compounds, such as the binary compounds and the ternary compounds, may exist in particles at uniform or non-uniform concentrations. That is, the chemical formulas may refer to the types of elements included in the compounds, and the element ratios in the compounds may be different from one another.

In an embodiment, the quantum dots QD1 and QD2 may have a full width of half maximum (FWHM) of a light emission wavelength spectrum of about 45 nm or less, and, in an embodiment, about 40 nm or less, and, in an embodiment, about 30 nm or less, and may improve color purity or color reproduction in the range. Further, light emitted through the quantum dots QD1 and QD2 may be emitted in all directions, and thus a wide viewing angle may be improved.

The forms of the quantum dots QD1 and QD2 are not particularly limited to forms generally used in the related art. For example, nanoparticles, nanotubes, nanowires, nanofibers, or nanoplatelet particles that have a spherical, pyramidal, multi-arm, or cubic shape may be used.

The quantum dots QD1 and QD2 may adjust the color of emitted light by adjusting the particle size or the element ratio in the compound. Accordingly, the quantum dots QD1 and QD2 may have various light emission colors, such as blue, red, and green. Accordingly, the first quantum dots QD1 may convert the source light provided by the first light emitting element OLED1 into red light having a wavelength range different from that of the source light. Thus, the display device DD may output red light through the first pixel region PXA-R.

The second quantum dots QD2 may convert the source light provided by the second light emitting element OLED2 into green light having a wavelength range different from that of the source light. Thus, the display device DD may output green light through the second pixel region PXA-G.

The first capping layer CP1 may be disposed on the light adjustment layer CCL. The first capping layer CP1 may cover the light adjustment layer CCL. The first capping layer CP1 may cover the bank layer BK, the light transmitting layer LCP, and the light conversion layers WCP.

The first capping layer CP1 may include an inorganic material. The first capping layer CP1 may prevent or substantially prevent infiltration of moisture or foreign matter into the light adjustment layer CCL.

The filling member FL may be disposed on the first capping layer CP1. The filling member FL may be disposed between the second capping layer CP2 to be described below and the first capping layer CP1. A separation space between the first capping layer CP1 and the second capping layer CP2 may be filled with the filling member FL. However, without being limited thereto, the filling member FL may be omitted.

The color filter layer CFL, the low-refractive index layer LR, and the second capping layer CP2 may be sequentially disposed on the rear surface of the upper substrate SUB2 in the third direction DR3. The rear surface of the upper substrate SUB2 may be defined as a surface facing the upper surface of the lower substrate SUB1.

The second capping layer CP2 may be disposed on the lower surface of the low-refractive index layer LR that faces the display panel DP. In an embodiment, the second capping layer CP2 may include an inorganic material. The second capping layer CP2 may prevent or substantially prevent infiltration of moisture or gas into the low-refractive index layer LR.

The low-refractive index layer LR may be disposed between the second capping layer CP2 and the color filter layer CFL. The low-refractive index layer LR may have a refractive index lower than the refractive indexes of the first and second light conversion layers WCP1 and WCP2 and the light transmitting layer LCP. For example, the low-refractive index layer LR may have a refractive index of 1.1 to 1.5. In an embodiment, the low-refractive index layer LR may have a refractive index of 1.1 to 1.35. However, the refractive index of the low-refractive index layer LR is not limited to the above numerical examples. The low-refractive index layer LR may include a low-refractive index organic film having a relatively low refractive index. The low-refractive index layer LR may further include hollow particles and/or voids dispersed in the organic film. The refractive index of the low-refractive index layer LR may be adjusted by the percentage of the hollow particles and/or the voids.

The low-refractive index layer LR disposed over the light adjustment layer CCL may input light not converted by the light conversion layers WCP1 and WCP2 and output from the upper surfaces of the light conversion layers WCP1 and WCP2 into the light conversion layers WCP1 and WCP2 by using the refractive index of the low-refractive index layer LR. The light input into the light conversion layers WCP1 and WCP2 by the low-refractive index layer LR may be converted by the quantum dots QD1 and QD2. That is, the low-refractive index layer LR may improve the light emission efficiency of the display device DD through the light recirculation using the refractive index of the low-refractive index layer LR.

The low-refractive index layer LR may include a material having a high light transmittance. For example, the low-refractive index layer LR may have a high light transmittance of 90% or more. Since the low-refractive index layer LR has a high light transmittance, the transmittance of light output toward the front surface of the display module DM may not be lowered.

The color filter layer CFL may be disposed on the surface of the upper substrate SUB2 that faces the display panel DP. The color filter layer CFL may include a first color filter CF1, a second color filter CF2, and a third color filter CF3. The first to third color filters CF1, CF2, and CF3 may be disposed to correspond to the first to third emissive regions EA1, EA2, and EA3, respectively, when viewed from above the plane. For example, the first color filter CF1 may overlap the first emissive region EA1, the second color filter CF2 may overlap the second emissive region EA2, and the third color filter CF3 may overlap the third emissive region EA3.

Each of the first to third color filters CF1, CF2, and CF3 may include a base resin and a pigment or dye dispersed in the base resin. Each of the first to third color filters CF1, CF2, and CF3 may transmit light having a specific wavelength range and may absorb most of light having a wavelength range other than the specific wavelength range.

For example, the first color filter CF1 may include a red color filter, the second color filter CF2 may include a green color filter, and the third color filter CF3 may include a blue color filter. The red color filter may transmit red light and may absorb most of green light and blue light. The green color filter may transmit green light and may absorb most of red light and blue light. The blue color filter may transmit blue light and may absorb most of red light and green light.

The first color filter CF1 may overlap the first light conversion layer WCP1. The first color filter CF1 may transmit red light provided from the first light conversion layer WCP1. For example, the first light conversion layer WCP1 may convert blue light provided from the first light emitting element OLED1 into red light, and the first color filter CF1 may transmit the red light provided from the first light conversion layer WCP1. The first color filter CF1 may absorb green light and blue light incident toward the first color filter CF1. The first color filter CF1 may absorb a light beam not converted by the first light conversion layer WCP1 among light beams incident toward the first color filter CF1, thereby preventing or substantially preventing deterioration in color purity in the first pixel region PXA-R.

The second color filter CF2 may overlap the second light conversion layer WCP2. The second color filter CF2 may transmit green light provided from the second light conversion layer WCP2. For example, the second light conversion layer WCP2 may convert blue light provided from the second light emitting element OLED2 into green light, and the second color filter CF2 may transmit the green light provided from the second light conversion layer WCP2. The second color filter CF2 may absorb red light and blue light incident toward the second color filter CF2. The second color filter CF2 may absorb a light beam not converted by the second light conversion layer WCP2 among light beams incident toward the second color filter CF2, thereby preventing or substantially preventing deterioration in color purity in the second pixel region PXA-G.

The third color filter CF3 may overlap the light transmitting layer LCP. The third color filter CF3 may transmit blue light provided from the light transmitting layer LCP. For example, the light transmitting layer LCP may transmit blue light provided from the third light emitting element OLED3, and the third color filter CF3 may transmit the blue light provided from the light transmitting layer LCP. The third color filter CF3 may absorb red light and green light incident toward the third color filter CF3. The third color filter CF3 may absorb a light beam not converted by the light transmitting layer LCP among light beams incident toward the third color filter CF3, thereby preventing or substantially preventing deterioration in color purity in the third pixel region PXA-B.

External light, such as natural light, may be incident toward the display panel DP from outside the display device DD. The external light may include red light, green light, and blue light. If the display panel DP does not include the color filter layer CFL, the external light incident toward the display panel DP may be reflected by conductive patterns (e.g., signal lines and electrodes) in the display panel DP and may be provided to a user, and the user may visually recognize the reflected light.

The first to third color filters CF1, CF2, and CF3 may prevent or substantially prevent reflection of external light. For example, the first color filter CF1 may be a red color filter. The first color filter CF1 may filter the external light into red light by absorbing light corresponding to green light and blue light of the external light. Likewise, the second color filter CF2 may be a green color filter. The second color filter CF2 may filter the external light into green light by absorbing light corresponding to red light and blue light of the external light. The third color filter CF3 may be a blue color filter. The third color filter CF3 may filter the external light into blue light by absorbing light corresponding to red light and green light of the external light.

In an embodiment, at least two color filters among the first to third color filters CF1, CF2, and CF3 may overlap each other in the peripheral region NPXA. For example, the first to third color filters CF1, CF2, and CF3 may be disposed to overlap each other in the third direction DR3 in the peripheral region NPXA. For example, the first color filter CF1 may be disposed under the third color filter CF3, and the second color filter CF2 may be disposed under the first color filter CF1.

The first to third color filters CF1, CF2, and CF3 disposed to overlap each other may extend above the bank layers BK and may overlap each other. The first to third color filters CF1, CF2, and CF3 disposed to overlap each other may block light passing through the peripheral region NPXA to prevent or substantially prevent color mixing between the first to third pixel regions PXA-R, PXA-G, and PXA-B.

The upper substrate SUB2 may be disposed on the color filter layer CFL. The upper substrate SUB2 may include a glass substrate, a polymer substrate, or an organic/inorganic composite substrate. The upper substrate SUB2 may include a front surface and a rear surface that are parallel to the first direction DR1 and the second direction DR2. The rear surface of the upper substrate SUB2 may face the upper surface of the lower substrate SUB1. The upper substrate SUB2 may provide a base surface on which the components of the light control layer OP are stacked.

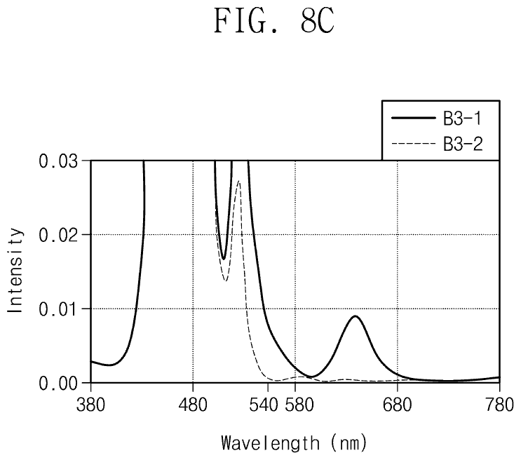

FIG. 7A is a cross-sectional view of a display device according to a comparative example. FIG. 7B is a cross-sectional view of the display device according to an embodiment of the present disclosure. FIGS. 8A to 8C are views for explaining color purity.

The display device DD of FIG. 7B is the same as the display device DD of FIG. 6 and, therefore, further description thereof will be omitted.

A display device DD′ of FIG. 7A is the same as the display device DD of FIG. 7B, except for the barrier walls GB being omitted and, therefore, a detailed description thereof will be omitted.

Although a case in which light is output from the second light emitting element OLED2 is described with reference to FIGS. 7A and 7B, the description may be applied the same to the first light emitting element OLED1 and the third light emitting element OLED3.

Referring to FIG. 7A, light may be output from the light emitting elements OLED. An angle formed by the light with a vertical line SLP parallel to the third direction DR3 may be defined as a light output angle.

For example, light output from the second light emitting element OLED2 may be incident toward the second light conversion layer WCP2. Green light into which the light is converted from blue light by the second light conversion layer WCP2 may pass through the second color filter CF2 and may be provided to the outside.

However, when the light output angle is gradually increased, the light output from the second light emitting element OLED2 may be incident toward the first light conversion layer WCP1, and red light into which the light is converted by the first light conversion layer WCP1 may be incident to the second pixel region PXA-G or the third pixel region PXA-B.

Further, the light output from the second light emitting element OLED2 may be incident toward the light transmitting layer LCP, and blue light transmitting through the light transmitting layer LCP may be incident to the first pixel region PXA-R or the second pixel region PXA-G.

Accordingly, the light from the pixel regions PXA-R, PXA-G, and PXA-B may be mixed and provided to the outside, and therefore color purity may be decreased.

Referring to FIG. 7B, however, the display device DD according to an embodiment of the present disclosure includes the barrier walls GB. The barrier walls GB may include a black material. In an embodiment, the barrier walls GB include the black material, such that the barrier walls GB may absorb light. In an embodiment, for example, the barrier walls GB may have a light absorbance of 0.01/μm.

Light having a large light output angle may be absorbed by the barrier walls GB. Accordingly, the light having the large light output angle may not be incident to the first light conversion layer WCP1 or the light transmitting layer LCP. Thus, light having different colors may be provided to the outside without being mixed such that color purity may be increased.

Referring to FIGS. 8A to 8C, FIG. 8A is a view illustrating the wavelength of red light provided to the outside by the unit pixels PXU. FIG. 8B is a view illustrating the wavelength of green light provided to the outside by the unit pixels PXU. FIG. 8C is a view illustrating the wavelength of blue light provided to the outside by the unit pixels PXU.

In each of the graphs illustrated in FIGS. 8A to 8C, the x-axis may represent wavelength, and the y-axis may represent intensity.

The intensity of the red light may be higher in a wavelength range of 580 nm to 780 nm than in other wavelength ranges. The intensity of the green light may be higher in a wavelength range of 480 nm to 580 nm than in other wavelength ranges. The intensity of the blue light may be higher in a wavelength range of 380 nm to 540 nm than in other wavelength ranges.

Referring to FIGS. 5A, 7A, 7B, and 8A, graph R1-1 is a graph depicting the wavelength of red light provided by the unit pixels PXU when the barrier walls GB do not exist. Graph R1-2 is a graph depicting the wavelength of red light provided by the unit pixels PXU when the barrier walls GB exist.

In the example showing the result of graph R1-1, it can be seen that in addition to red light output from a first pixel region PXA-R′, green light is output from a second pixel region PXA-G′ and blue light is output from a third pixel region PXA-B′.

In the embodiment according to the present disclosure showing the result of graph R1-2, it can be seen that as a light beam having a large light output angle among light beams output from the first light emitting element OLED1 is absorbed by the barrier walls GB, the intensities of blue light and green light output from the unit pixels PXU are lowered.

Referring to FIGS. 7A, 7B, and 8B, graph G2-1 is a graph depicting the wavelength of green light provided by the unit pixels PXU when the barrier walls GB do not exist. Graph G2-2 is a graph depicting the wavelength of green light provided by the unit pixels PXU when the barrier walls GB exist.

In the example showing the result of graph G2-1, it can be seen that in addition to green light output from the second pixel region PXA-G′, red light is output from the first pixel region PXA-R′ and blue light is output from the third pixel region PXA-B′.

In the embodiment according to the present disclosure showing the result of graph G2-2, it can be seen that as a light beam having a large light output angle among light beams output from the second light emitting element OLED2 is absorbed by the barrier walls GB, the intensities of red light and blue light output from the unit pixels PXU are lowered.

Referring to FIGS. 7A, 7B, and 8C, graph B3-1 is a graph depicting the wavelength of blue light provided by the unit pixels PXU when the barrier walls GB do not exist. Graph B3-2 is a graph depicting the wavelength of blue light provided by the unit pixels PXU when the barrier walls GB exist.

In the example showing the result of graph B3-1, it can be seen that in addition to blue light output from the third pixel region PXA-B′, red light is output from the first pixel region PXA-R′ and green light is output from the second pixel region PXA-G′.

In the embodiment according to the present disclosure showing the result of graph B3-2, it can be seen that as a light beam having a large light output angle among light beams output from the third light emitting element OLED3 is absorbed by the barrier walls GB, the intensities of red light and green light output from the unit pixels PXU are lowered.

Referring to FIGS. 8A to 8C, through graphs R1-1 to B3-2, it can be seen that the color purity of light provided to the outside through the first to third emissive regions PXA-R, PXA-G, and PXA-B is increased.

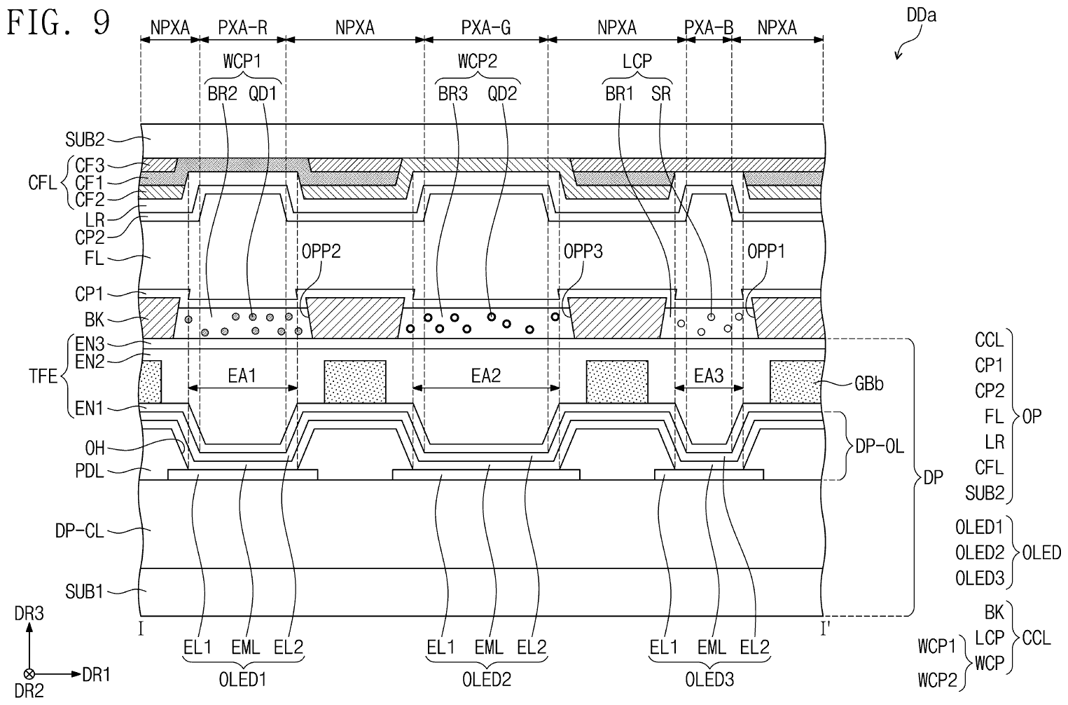

FIG. 9 is a cross-sectional view of a display device DDa according to an embodiment of the present disclosure.

A lower substrate SUB1, a circuit layer DP-CL, light emitting elements OLED, a pixel defining layer PDL, and a light control layer OP of FIG. 9 may be the same as the lower substrate SUB1, the circuit layer DP-CL, the light emitting elements OLED, the pixel defining layer PDL, and the light control layer OP of FIG. 6 and, therefore, description thereof will be omitted or will be briefly described.

Referring to FIG. 9, first electrodes EL1 may be disposed on the circuit layer DP-CL. The first electrodes EL1 may be anodes or cathodes. Further, the first electrodes EL1 may be pixel electrodes. The first electrodes EL1 may be transmissive electrodes, transflective electrodes, or reflective electrodes.

The pixel defining layer PDL may be disposed on the circuit layer DP-CL. The pixel defining layer PDL may cover portions of the first electrodes EL1. Light emitting openings OH may be defined by the pixel defining layer PDL. The light emitting openings OH of the pixel defining layer PDL may expose at least portions of the first electrodes EL1.

An emissive layer EML may be disposed on the first electrodes EL1. The emissive layer EML may be disposed on the pixel defining layer PDL. The emissive layer EML may be commonly disposed in first to third emissive regions EA1, EA2, and EA3 and a non-emissive region. The emissive layer EML may be disposed in the light emitting openings OH. The emissive layer EML may cover the pixel defining layer PDL.

A second electrode EL2 may be disposed on the emissive layer EML. The second electrode EL2 may cover the emissive layer EML. The second electrode EL2 may be a common electrode. The second electrode EL2 may be a cathode or an anode, but embodiments of the second electrode EL2 are not limited thereto. For example, when the first electrodes EL1 are anodes, the second electrode EL2 may be a cathode, and when the first electrodes EL1 are cathodes, the second electrode EL2 may be an anode. The second electrode EL2 may be a transmissive electrode, a transflective electrode, or a reflective electrode.

An encapsulation layer TFE may be disposed on the second electrode EL2. In an embodiment, the encapsulation layer TFE may include first to third encapsulation films EN1, EN2, and EN3. The first encapsulation film EN1 may cover the second electrode EL2.

Barrier walls GBb may be disposed on the first encapsulation film EN1. The barrier walls GBb may be disposed on an upper surface of the first encapsulation film EN1 that overlaps the pixel defining layer PDL. In an embodiment, the barrier walls GBb may include a black material. In an embodiment, the barrier walls GBb include the black material, and the barrier walls GBb may thereby absorb a portion of light output from the light emitting elements OLED. Accordingly, the barrier walls GBb may prevent or substantially prevent color mixing of the light. Thus, the color purity of the display device DDa may be improved.

The second encapsulation film EN2 may be disposed on the first encapsulation film EN1. The second encapsulation film EN2 may cover the barrier walls GBb. The third encapsulation film EN3 may be disposed on the second encapsulation film EN2.

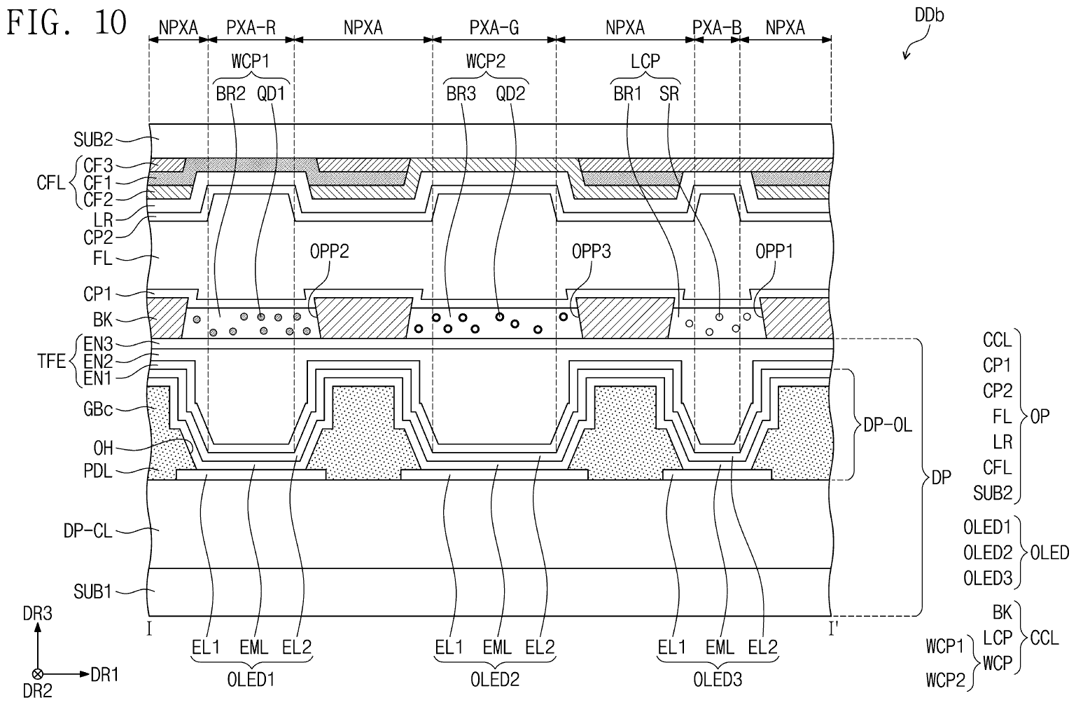

FIG. 10 is a cross-sectional view of a display device DDb according to an embodiment of the present disclosure.

A lower substrate SUB1, a circuit layer DP-CL, light emitting elements OLED, an encapsulation layer TFE, and a light control layer OP of FIG. 10 may be the same as the lower substrate SUB1, the circuit layer DP-CL, the light emitting elements OLED, the encapsulation layer TFE, and the light control layer OP of FIG. 6 and, therefore, description thereof will be omitted or will be briefly described.

Referring to FIG. 10, barrier walls GBc may be disposed on a pixel defining layer PDL. The barrier walls GBc may extend from an upper surface of the pixel defining layer PDL. Substantially, the barrier walls GBc may be integrally formed with the pixel defining layer PDL.

In an embodiment, a width of the pixel defining layer PDL in the first direction DR1 may be decreased farther away from an upper surface of the circuit layer DP-CL, and widths of the barrier walls GBc in the first direction DR1 may be constant. The width of the upper surface of the pixel defining layer PDL in the first direction DR1 may be greater than the widths of the barrier walls GBc in the first direction DR1.

Since the barrier walls GBc are disposed on the pixel defining layer PDL, the barrier walls GBc may absorb light beams having a large light output angle among light beams output from the light emitting elements OLED. Accordingly, the color purity of light provided to the outside from first to third pixel regions PXA-R, PXA-G, and PXA-B may be improved.

According to embodiments of the present disclosure, the barrier wall may be disposed between the adjacent light emitting elements. The barrier wall may absorb some of light beams output from the light emitting elements and may block color mixing with light beams output from other light emitting elements. Thus, the color purity of the display device may be improved.

While the present disclosure has been described with reference to some embodiments thereof, it will be apparent to those of ordinary skill in the art that various changes and modifications may be made thereto without departing from the spirit and scope of the present disclosure as set forth in the following claims.

What is claimed is:

1. A display device comprising:
a display panel comprising a circuit element layer and a light emitting element layer on the circuit element layer; and
a first light conversion layer, a second light conversion layer, and a light transmitting layer on the display panel and spaced apart from one another,
wherein the light emitting element layer comprises:
a pixel defining layer defining light emitting openings overlapping the first light conversion layer, the second light conversion layer, and the light transmitting layer;
a plurality of light emitting elements arranged in the light emitting openings, respectively; and
a barrier wall on the pixel defining layer, the barrier wall being black in color, and
wherein, when viewed from above a plane, the barrier wall is located between light emitting elements adjacent to each other among the plurality of light emitting elements and extends parallel to sides of the adjacent light emitting elements that face each other.

2. The display device of claim 1, wherein the plurality of light emitting elements comprise a first light emitting element, a second light emitting element, and a third light emitting element having different sizes, and
wherein the first light emitting element and the third light emitting element are arranged in a first direction when viewed from above the plane.

3. The display device of claim 2, wherein, when viewed from above the plane, the barrier wall is located between the first light emitting element and the third light emitting element and extends parallel to a side of the first light emitting element and a side of the third light emitting element in a second direction crossing the first direction, and the side of the first light emitting element and the side of the third light emitting element face each other.

4. The display device of claim 3, wherein, when viewed from above the plane, the second light emitting element and the first light emitting element are spaced apart from each other in a first diagonal direction, and the second light emitting element and the third light emitting element are spaced apart from each other in a second diagonal direction, the first diagonal direction crossing the first direction and the second direction, and the second diagonal direction crossing the first diagonal direction.

5. The display device of claim 4, wherein, when viewed from above the plane, the barrier wall is located between the first light emitting element and the second light emitting element and between the second light emitting element and the third light emitting element and extends in the first direction.

6. The display device of claim 1, wherein each of the plurality of light emitting elements comprises:
an anode on the circuit element layer;
an emissive layer on the anode; and
a cathode on the emissive layer.

7. The display device of claim 6, wherein the barrier wall is located on an upper surface of the pixel defining layer, and the emissive layer covers the pixel defining layer and the barrier wall.

8. The display device of claim 6, wherein the barrier wall and the pixel defining layer are integrally formed.

9. The display device of claim 1, further comprising:
a thin film encapsulation layer comprising a first inorganic layer on the light emitting element layer, an organic layer on the first inorganic layer, and a second inorganic layer on the organic layer.

10. The display device of claim 9, wherein the barrier wall is located on an upper surface of the first inorganic layer and overlaps the pixel defining layer.

11. The display device of claim 10, wherein the organic layer covers the barrier wall.

12. The display device of claim 1, wherein the barrier wall has a thickness of 1 μm to 3 μm.

13. The display device of claim 1, further comprising:
a first color filter on the first light conversion layer;
a second color filter on the second light conversion layer; and
a third color filter on the light transmitting layer.

14. A display device comprising:
a display panel; and
a first light conversion layer, a second light conversion layer, and a light transmitting layer on the display panel and spaced apart from one another,
wherein the display panel comprises:
a pixel defining layer defining a plurality of pixel openings;
a first light emitting element arranged in the pixel openings and overlapping the first light conversion layer;
a second light emitting element arranged in the pixel openings and overlapping the second light conversion layer;
a third light emitting element arranged in the pixel openings and spaced apart from the first light emitting element in a first direction, the third light emitting element overlapping the light transmitting layer; and
a barrier wall between the first light emitting element and the third light emitting element, and
wherein, when viewed from above a plane, a length of the barrier wall in a second direction crossing the first direction is longer than a length of the first light emitting element in the second direction and a length of the third light emitting element in the second direction.

15. The display device of claim 14, wherein the barrier wall is located between the first light emitting element and the second light emitting element and between the second light emitting element and the third light emitting element, and a length of the barrier wall in the first direction is longer than a length of the second light emitting element in the first direction.

16. The display device of claim 14, wherein each of the first light emitting element, the second light emitting element, and the third light emitting element comprises:
an anode, at least a portion of which is exposed from the pixel defining layer to an outside by the pixel openings;
an emissive layer on the anode; and
a cathode on the emissive layer.

17. The display device of claim 16, wherein the barrier wall is located on an upper surface of the pixel defining layer, and
wherein the emissive layer covers the pixel defining layer and the barrier wall.

18. The display device of claim 17, wherein the pixel defining layer and the barrier wall are integrally formed.

19. The display device of claim 14, further comprising:
a thin film encapsulation layer comprising a first inorganic layer on the first light emitting element, the second light emitting element, and the third light emitting element, an organic layer on the first inorganic layer, and a second inorganic layer on the organic layer.

20. The display device of claim 19, wherein the barrier wall is located on an upper surface of the first inorganic layer, and the organic layer covers the barrier wall.
